(19) United States
(12) Patent Application Publication
(10) Pub. No.: US 2023/0201975 A1
(43) Pub. Date: Jun. 29, 2023

(54) SOLDER BALL WITH CONCAVE-CONVEX STRUCTURE AND METHOD FOR PREPARING THE SAME

(71) Applicant: INDUSTRIAL TECHNOLOGY RESEARCH INSTITUTE, Hsinchu (TW)

(72) Inventors: Shou-Yi HO, Taoyuan City (TW); Jyh-Long JENG, New Taipei City (TW)

(73) Assignee: INDUSTRIAL TECHNOLOGY RESEARCH INSTITUTE, Hsinchu (TW)

(21) Appl. No.: 17/745,131

(22) Filed: May 16, 2022

(30) Foreign Application Priority Data
Dec. 28, 2021 (TW) 110149025

(51) Int. Cl. B23K 35/02; B23K 35/26

(52) U.S. Cl. CPC B23K 35/025; B23K 35/262; B23K 2103/08

(57) ABSTRACT

A solder ball with a concave-convex structure is provided. The solder ball with a concave-convex structure includes tin-bismuth alloy including a plurality of concave portions and convex portions on its surface. The height difference between the concave portions and the convex portions is between about 10 nanometers and about 200 nanometers. The proportion of tin in the tin-bismuth alloy is between about 28% and about 52%. A method for preparing the solder ball with a concave-convex structure is also provided.

### CROSS REFERENCE TO RELATED APPLICATIONS

This application claims priority of Taiwan Patent Application No. 110149025, filed on Dec. 28, 2021, the entirety of which is incorporated by reference herein.

### TECHNICAL FIELD

The present disclosure relates to a solder ball with a concave-convex structure.

### BACKGROUND

The display technology of micro-LED is a miniaturized LED array structure with self-luminous display characteristics, and each pixel can be driven independently, with high brightness, high contrast, low power consumption, high resolution and high color saturation.

At present, Micro-LEDs generally include epitaxy, mass transfer and repair technologies, among which mass-transfer technology is a key to whether micro-LED products can be commercialized, and the steps include transfer and die bonding. On the market, products by companies such as LuxVue use electrostatic force to adsorb tiny dies and have transfer heads that have a bipolar structure that can apply positive voltage and negative voltage to respectively grab and release the dies. X-Celeprint uses an elastomer imprint head to control the speed of the interface bonding to grab and release the die, and then transfer it to the substrate. There are two kinds of die-bonding materials, one is solder, and the other is anisotropic conductive film (ACF). Compared with solder, existing anisotropic conductive film can still conduct the circuit, but it needs to be pressed during the mass transfer, which makes it easy for the chip electrode to crack. On the other hand, the solder-based die-bonding material can be bonded directly onto the chip electrode after the tin is melted to avoid problems with electrode cracking. However, due to the problems with alignment accuracy in printing in the existing process, vacuum sputtering and evaporation is most commonly used to manufacture the die-bonding material, and it is relatively expensive, with a slow processing speed, and therefore does not meet the requirements for mass production.

### SUMMARY

In accordance with one embodiment of the present disclosure, a solder ball with a concave-convex structure is provided. The solder ball with a concave-convex structure includes a tin-bismuth alloy which includes a plurality of concave portions and convex portions on its surface, wherein the height difference between the concave portions and the convex portions is between 10 nm and 200 nm, and the proportion of tin in the tin-bismuth alloy is between 28% and 52%.

In accordance with one embodiment of the present disclosure, a method for preparing a solder ball with a concave-convex structure is provided. The preparation method includes providing an acidic etching solution, wherein the acidic etching solution includes an acid and a modifier; placing a solder ball in the acidic etching solution to perform an acidic etching step; and cleaning the solder ball subjected to the acidic etching step several times with a solution containing an antioxidant protective agent to prepare the disclosed solder ball with a concave-convex structure.

In accordance with one embodiment of the present disclosure, a solder paste is provided. The solder paste includes a colloidal composition including rosin, oleic acid, epoxy resin and organic polyacid; and the disclosed solder ball with a concave-convex structure mixed in the colloidal composition.

A detailed description is given in the following embodiments with reference to the accompanying drawings.

### BRIEF DESCRIPTION OF THE DRAWINGS

FIG. 1 is a schematic diagram of a solder ball with a concave-convex structure in accordance with one embodiment of the present disclosure;

FIG. 2A shows a TEM image of modified surface of T7-type solder balls in accordance with one embodiment of the present disclosure;

FIG. 2B shows a TEM image of height difference between a concave structure and a convex structure on surface of T7-type solder balls after modification in accordance with one embodiment of the present disclosure;

FIG. 3A shows a TEM image of modified surface of T7-type solder balls in accordance with one embodiment of the present disclosure;

FIG. 3B shows a TEM image of height difference between a concave structure and a convex structure on surface of T7-type solder balls after modification in accordance with one embodiment of the present disclosure;

FIG. 4A shows a TEM image of modified surface of T10-type solder balls in accordance with one embodiment of the present disclosure;

FIG. 4B shows a TEM image of height difference between a concave structure and a convex structure on surface of T10-type solder balls after modification in accordance with one embodiment of the present disclosure;

FIG. 5A shows a TEM image of modified surface of T10-type solder balls in accordance with one embodiment of the present disclosure;

FIG. 5B shows a TEM image of height difference between a concave structure and a convex structure on surface of T10-type solder balls after modification in accordance with one embodiment of the present disclosure

### DETAILED DESCRIPTION

In the present disclosure, the self-assembled solder paste including the solder balls with the concave-convex structure is patterned by a steel-plate printing process. After reflow, it is assembled to the electrode, and then the micro light-emitting diode is joined thereon. As the size of the solder balls decreases, its surface area increases and the concentration of the oxide layer increases, which affects the reflowability and the connection characteristics between the electrodes. In the present disclosure, through surface modification, the solder balls can be self-aggregated on the electrodes after reflow, which can speed up the process speed, solve the reflowability, and improve the connection with the electrodes, so that the micro-LED display can be mass-produced. In addition, the disclosed self-assembled solder paste with low-temperature (160° C.) reflow characteristics can also solve the problem that the imprint head of the mass transfer head fails due to high temperature reflow (260° C.).

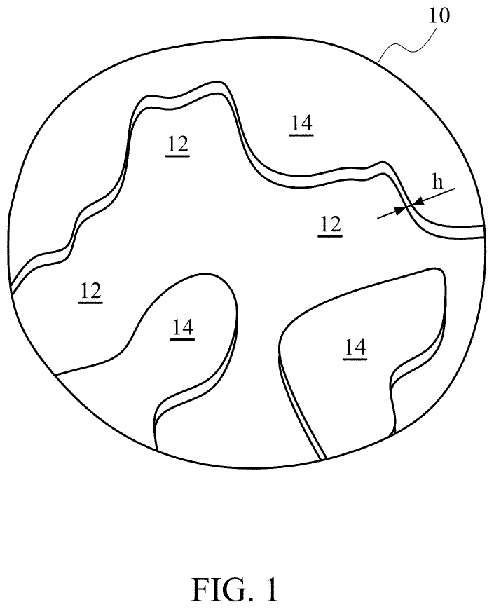

Referring to FIG. 1, in accordance with one embodiment of the present disclosure, a solder ball 10 with concave-convex structure is provided. FIG. 1 is a schematic diagram of the solder ball 10 with concave-convex structure.

As shown in FIG. 1, the solder ball 10 with concave-convex structure includes tin-bismuth alloy which includes a plurality of concave portions 12 and convex portions 14 on the surface thereof. The height difference h between the concave portions 12 and the convex portions 14 is between about 10 nm and about 200 nm. The proportion of tin in the tin-bismuth alloy is between about 28% and about 52%.

In some embodiments, the particle size of the solder ball 10 with concave-convex structure is between about 0.5 μm and about 12 μm.

In accordance with one embodiment of the present disclosure, a solder paste is provided. The solder paste includes colloidal composition and solder balls mixed in the colloidal composition. The colloidal composition includes rosin, oleic acid, epoxy resins such as 1,2-cyclohexanedicarboxylate diglycidyl ester, and organic polyacids. The mixed solder ball is shown in FIG. 1. The solder ball 10 with concave-convex structure includes a tin-bismuth alloy which includes a plurality of concave portions 12 and convex portions 14 on its surface. The height difference h between the concave portions 12 and the convex portions 14 is between about 10 nm and about 200 nm. The proportion of tin in the tin-bismuth alloy is between about 28% and about 52%.

In some embodiments, in the colloidal composition, the ratio among rosin, oleic acid, 1,2-cyclohexanedicarboxylate diglycidyl ester and organic polyacid is about 30-50: 5-20:5-20: 30-50.

In some embodiments, the organic polyacid includes glutaric acid.

In accordance with one embodiment of the present disclosure, a method for preparing a solder ball with a concave-convex structure is provided, including the following steps. First, an acidic etching solution is provided. Next, a solder ball is placed in the acidic etching solution to perform an acidic etching step. Next, the solder ball subjected to the acidic etching step is cleaned with a solution containing an antioxidant protective agent several times to prepare a solder ball with a concave-convex structure. The acidic etching solution includes an acid and a modifier. The prepared solder ball with a concave-convex structure is shown in FIG. 1. The solder ball 10 with concave-convex structure includes a tin-bismuth alloy which includes a plurality of concave portions 12 and convex portions 14 on its surface. The height difference h between the concave portions 12 and the convex portions 14 is between about 10 nm and about 200 nm. The proportion of tin in the tin-bismuth alloy is between about 28% and about 52%.

In some embodiments, the acid in the acidic etching solution includes inorganic acids such as hydrochloric acid, sulfuric acid, nitric acid, oxalic acid or carboxylic acid. In some embodiments, the acid in the acidic etching solution includes organic acids such as glutaric acid, hexanedioic acid or oleic acid.

In some embodiments, the viscosity of the acidic etching solution is between about 30 cps and about 3000 cps.

In some embodiments, the modifier in the acidic etching solution includes polyols or ionic polymers. In some embodiments, the polyol includes ethylene glycol, glycerol or propylene glycol. In some embodiments, the ionic polymer includes anionic polyacrylamide, acid salt of styrene-maleimide copolymer or ammonium salt of styrene-maleic anhydride copolymer.

In some embodiments, the period of the acidic etching step is between about 5 minutes and about 4 hours.

In some embodiments, the antioxidant protective agent includes rosin, rosin derivatives, fatty acid, titanium complex, zirconium complex or long-carbon-chain thiol.

The effect of the light-color conversion layer of the embodiment of the present disclosure will be described below with experimental examples and comparative examples.

First, the brands and models of materials and testing instruments used in the following preparation examples and examples will be described.

T7-type solder ball: manufacturer: 5N plus; particle size distribution: between 2 μm and 11 μm.

T10-type solder ball: manufacturer: 5N plus; particle size distribution: between 1 μm and 4 μm.

Scanning electron microscope (SEM): FE-SEM JEOL JSM-6500F.

Focused ion beam (FIB): Thermal Fisher G4.

Transmission electron microscope (TEM): JEOL JEM-2100F.

### Preparation Example 1

Preparation of solder ball (I) with concave-convex structure (T7-type solder ball; in 1N hydrochloric acid solution for 5 minutes)

2 g of T7-type solder balls were placed in a 1N hydrochloric acid solution (viscosity: 35.5 cps) containing 30% acid salt (modifier) of styrene-maleimide copolymer (SMA1000I), mixed and stirred for 5 minutes to perform an acidic etching step. Next, the solder balls were centrifuged to remove liquid. Next, the solder balls were washed with an ethanol solution containing 30 wt % rosin after aeration several times to obtain the modified solder balls (I).

The elemental analysis of the modified solder ball was performed by SEM to obtain the composition ratio of tin in the tin-bismuth alloy, and sliced by FIB. The height of the concave structure and convex structure on the surface of the solder ball was measured by TEM. The composition ratio of tin and the height difference between the concave and convex are shown in Table 1.

### Preparation Example 2

Preparation of solder ball (II) with concave-convex structure (T7-type solder ball; in 1N hydrochloric acid solution for 30 minutes)

2 g of T7-type solder balls were placed in a 1N hydrochloric acid solution (viscosity: 35.5 cps) containing 30% acid salt (modifier) of styrene-maleimide copolymer (SMA1000I), mixed and stirred for 30 minutes to perform an acidic etching step. Next, the solder balls were centrifuged to remove liquid. Next, the solder balls were washed with an ethanol solution containing 30 wt % rosin after aeration several times to obtain the modified solder balls (II).

The elemental analysis of the modified solder ball was performed by SEM to obtain the composition ratio of tin in the tin-bismuth alloy, and sliced by FIB. The height of the concave structure and convex structure on the surface of the solder ball was measured by TEM. The composition ratio of tin and the height difference between the concave and convex are shown in Table 1.

### Preparation Example 3

Preparation of solder ball (III) with concave-convex structure (T7-type solder ball; in 1N hydrochloric acid solution for 30 minutes)

2 g of T7-type solder balls were placed in a 1N hydrochloric acid solution (viscosity: 2156 cps) containing 40% acid salt (modifier) of styrene-maleimide copolymer (SMA1000I), mixed and stirred for 30 minutes to perform an acidic etching step. Next, the solder balls were centrifuged to remove liquid. Next, the solder balls were washed with an ethanol solution containing 30 wt % rosin after aeration several times to obtain the modified solder balls (III).

The elemental analysis of the modified solder ball was performed by SEM to obtain the composition ratio of tin in the tin-bismuth alloy, and sliced by FIB. The height of the concave structure and convex structure on the surface of the solder ball was measured by TEM. The composition ratio of tin and the height difference between the concave and convex are shown in Table 1.

### Preparation Example 4

Preparation of solder ball (IV) with concave-convex structure (T7-type solder ball; in 1N hydrochloric acid solution for 30 minutes)

2 g of T7-type solder balls were placed in a 1N hydrochloric acid/glycerol solution (viscosity: 316.5 cps), mixed and stirred for 30 minutes to perform an acidic etching step. Next, the solder balls were centrifuged to remove liquid. Next, the solder balls were washed with an ethanol solution containing 30 wt % rosin after aeration several times to obtain the modified solder balls (IV).

The elemental analysis of the modified solder ball was performed by SEM to obtain the composition ratio of tin in the tin-bismuth alloy, and sliced by FIB. The height of the concave structure and convex structure on the surface of the solder ball was measured by TEM. The composition ratio of tin and the height difference between the concave and convex are shown in Table 1.

### Preparation Example 5

Preparation of solder ball (V) with concave-convex structure (T7-type solder ball; in 1N hydrochloric acid solution for 2 hours)

2 g of T7-type solder balls were placed in a 1N hydrochloric acid solution (viscosity: 35.5 cps) containing 30% acid salt (modifier) of styrene-maleimide copolymer (SMA1000I), mixed and stirred for 2 hours to perform an acidic etching step. Next, the solder balls were centrifuged to remove liquid. Next, the solder balls were washed with an ethanol solution containing 30 wt % rosin after aeration several times to obtain the modified solder balls (V).

The elemental analysis of the modified solder ball was performed by SEM to obtain the composition ratio of tin in the tin-bismuth alloy, and sliced by FIB. The height of the concave structure and convex structure on the surface of the solder ball was measured by TEM. The composition ratio of tin and the height difference between the concave and convex are shown in Table 1.

### Preparation Example 6

Preparation of solder ball (VI) with concave-convex structure (T7-type solder ball; in 2N hydrochloric acid solution for 5 minutes)

2 g of T7-type solder balls were placed in a 2N hydrochloric acid solution (viscosity: 37.8 cps) containing 30% acid salt (modifier) of styrene-maleimide copolymer (SMA1000I), mixed and stirred for 5 minutes to perform an acidic etching step. Next, the solder balls were centrifuged to remove liquid. Next, the solder balls were washed with an ethanol solution containing 30 wt % rosin after aeration several times to obtain the modified solder balls (VI).

The elemental analysis of the modified solder ball was performed by SEM to obtain the composition ratio (the average value of measurement in three areas was taken) of tin in the tin-bismuth alloy, and sliced by FIB. The height of the concave structure and convex structure on the surface of the solder ball was measured by TEM. The composition ratio of tin and the height difference between the concave and convex are shown in Table 1.

### Preparation Example 7

Preparation of solder ball (VII) with concave-convex structure (T7-type solder ball; in 2N hydrochloric acid solution for 30 minutes)

2 g of T7-type solder balls were placed in a 2N hydrochloric acid solution (viscosity: 37.8 cps) containing 30% acid salt (modifier) of styrene-maleimide copolymer (SMA1000I), mixed and stirred for 30 minutes to perform an acidic etching step. Next, the solder balls were centrifuged to remove liquid. Next, the solder balls were washed with an ethanol solution containing 30 wt % rosin after aeration several times to obtain the modified solder balls (VII).

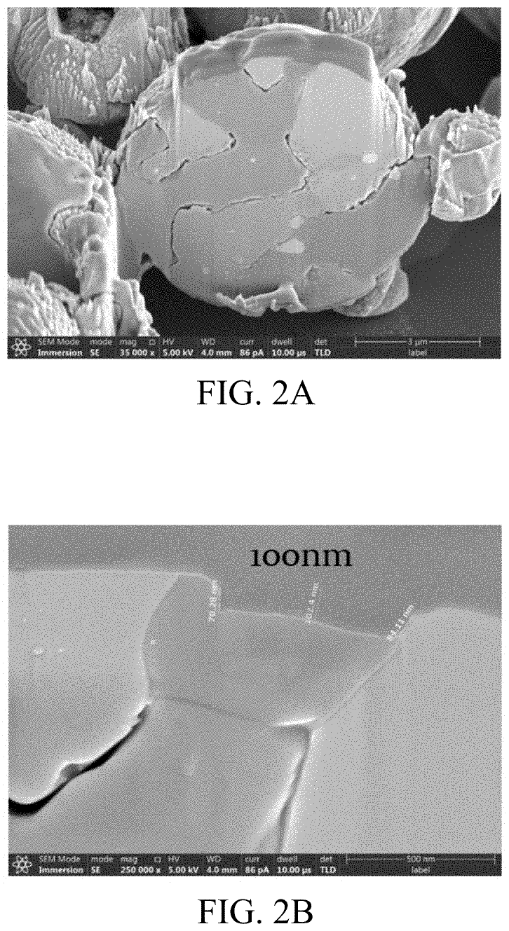

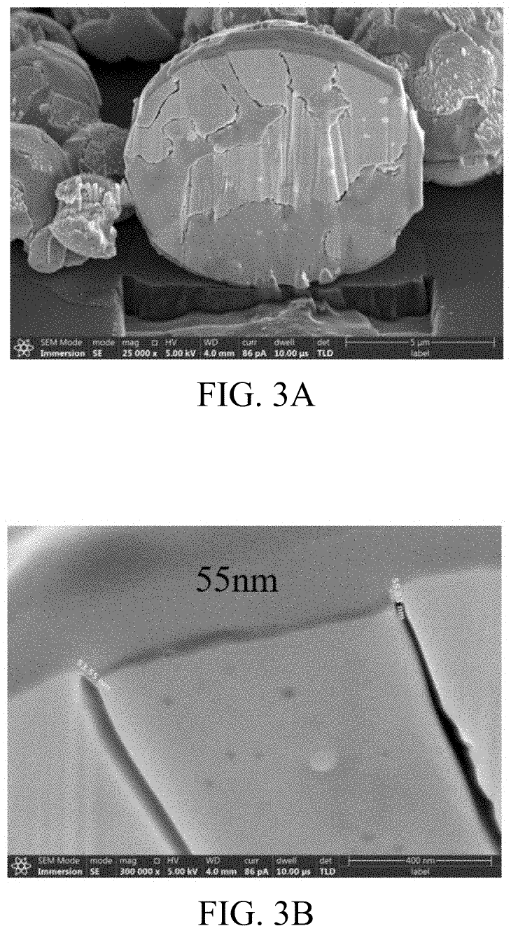

The elemental analysis of the modified solder ball was performed by SEM to obtain the composition ratio of tin in the tin-bismuth alloy, and sliced by FIB. The height of the concave structure and convex structure on the surface of the solder ball was measured by TEM. In this preparation example, a solder ball (VII) was taken and measured by TEM. The particle size thereof was 7 μm, and the surface appearance thereof is shown in FIG. 2A. The measured height difference between the concave and convex was about 100 nm (as shown in FIG. 2B). A solder ball (VII) was taken and measured by TEM. The particle size thereof was 10 μm, and the surface appearance thereof is shown in FIG. 3A. The measured height difference between the concave and convex was about 55 nm (as shown in FIG. 3B). The composition ratio of tin and the height difference between the concave and convex are shown in Table 1.

### Preparation Example 8

Preparation of solder ball (VIII) with concave-convex structure (T7-type solder ball; in 2N hydrochloric acid solution for 2 hours)

2 g of T7-type solder balls were placed in a 2N hydrochloric acid solution (viscosity: 37.8 cps) containing 30% acid salt (modifier) of styrene-maleimide copolymer (SMA1000I), mixed and stirred for 2 hours to perform an acidic etching step. Next, the solder balls were centrifuged to remove liquid. Next, the solder balls were washed with an ethanol solution containing 30 wt % rosin after aeration several times to obtain the modified solder balls (VIII).

The elemental analysis of the modified solder ball was performed by SEM to obtain the composition ratio of tin in the tin-bismuth alloy, and sliced by FIB. The height of the concave structure and convex structure on the surface of the solder ball was measured by TEM. The composition ratio of tin and the height difference between the concave and convex are shown in Table 1.

### Preparation Example 9

Preparation of solder ball (IX) with concave-convex structure (T10-type solder ball; in 1N hydrochloric acid solution for 5 minutes)

2 g of T10-type solder balls were placed in a 1N hydrochloric acid solution (viscosity: 35.5 cps) containing 30% acid salt (modifier) of styrene-maleimide copolymer (SMA1000I), mixed and stirred for 5 minutes to perform an acidic etching step. Next, the solder balls were centrifuged to remove liquid. Next, the solder balls were washed with an ethanol solution containing 30 wt % rosin after aeration several times to obtain the modified solder balls (IX).

The elemental analysis of the modified solder ball was performed by SEM to obtain the composition ratio of tin in the tin-bismuth alloy, and sliced by FIB. The height of the concave structure and convex structure on the surface of the solder ball was measured by TEM. The composition ratio of tin and the height difference between the concave and convex are shown in Table 2.

### Preparation Example 10

Preparation of solder ball (X) with concave-convex structure (T10-type solder ball; in 1N hydrochloric acid solution for 30 minutes)

2 g of T10-type solder balls were placed in a 1N hydrochloric acid solution (viscosity: 35.5 cps) containing 30% acid salt (modifier) of styrene-maleimide copolymer (SMA1000I), mixed and stirred for 30 minutes to perform an acidic etching step. Next, the solder balls were centrifuged to remove liquid. Next, the solder balls were washed with an ethanol solution containing 30 wt % rosin after aeration several times to obtain the modified solder balls (X).

The elemental analysis of the modified solder ball was performed by SEM to obtain the composition ratio of tin in the tin-bismuth alloy, and sliced by FIB. The height of the concave structure and convex structure on the surface of the solder ball was measured by TEM. The composition ratio of tin and the height difference between the concave and convex are shown in Table 2.

### Preparation Example 11

Preparation of solder ball (XI) with concave-convex structure (T10-type solder ball; in 1N hydrochloric acid solution for 30 minutes)

2 g of T10-type solder balls were placed in a 1N hydrochloric acid solution (viscosity: 2156 cps) containing 40% acid salt (modifier) of styrene-maleimide copolymer (SMA1000I), mixed and stirred for 30 minutes to perform an acidic etching step. Next, the solder balls were centrifuged to remove liquid. Next, the solder balls were washed with an ethanol solution containing 30 wt % rosin after aeration several times to obtain the modified solder balls (XI).

The elemental analysis of the modified solder ball was performed by SEM to obtain the composition ratio of tin in the tin-bismuth alloy, and sliced by FIB. The height of the concave structure and convex structure on the surface of the solder ball was measured by TEM. The composition ratio of tin and the height difference between the concave and convex are shown in Table 2.

### Preparation Example 12

Preparation of solder ball (XII) with concave-convex structure (T10-type solder ball; in 1N hydrochloric acid solution for 30 minutes)

2 g of T10-type solder balls were placed in a IN hydrochloric acid/glycerol solution (viscosity: 316.5 cps), mixed and stirred for 30 minutes to perform an acidic etching step. Next, the solder balls were centrifuged to remove liquid. Next, the solder balls were washed with an ethanol solution containing 30 wt % rosin after aeration several times to obtain the modified solder balls (XII).

The elemental analysis of the modified solder ball was performed by SEM to obtain the composition ratio of tin in the tin-bismuth alloy, and sliced by FIB. The height of the concave structure and convex structure on the surface of the solder ball was measured by TEM. The composition ratio of tin and the height difference between the concave and convex are shown in Table 2.

### Preparation Example 13

Preparation of solder ball (XIII) with concave-convex structure (T10-type solder ball; in 1N hydrochloric acid solution for 2 hours)

2 g of T10-type solder balls were placed in a iN hydrochloric acid solution (viscosity: 35.5 cps) containing 30% acid salt (modifier) of styrene-maleimide copolymer (SMA1000I), mixed and stirred for 2 hours to perform an acidic etching step. Next, the solder balls were centrifuged to remove liquid. Next, the solder balls were washed with an ethanol solution containing 30 wt % rosin after aeration several times to obtain the modified solder balls (XIII).

The elemental analysis of the modified solder ball was performed by SEM to obtain the composition ratio of tin in the tin-bismuth alloy, and sliced by FIB. The height of the concave structure and convex structure on the surface of the solder ball was measured by TEM. The composition ratio of tin and the height difference between the concave and convex are shown in Table 2.

### Preparation Example 14

Preparation of solder ball (XIV) with concave-convex structure (T10-type solder ball; in 2N hydrochloric acid solution for 5 minutes)

2 g of T10-type solder balls were placed in a 2N hydrochloric acid solution (viscosity: 37.8 cps) containing 30% acid salt (modifier) of styrene-maleimide copolymer (SMA1000I), mixed and stirred for 5 minutes to perform an acidic etching step. Next, the solder balls were centrifuged to remove liquid. Next, the solder balls were washed with an ethanol solution containing 30 wt % rosin after aeration several times to obtain the modified solder balls (XIV).

The elemental analysis of the modified solder ball was performed by SEM to obtain the composition ratio of tin in the tin-bismuth alloy, and sliced by FIB. The height of the concave structure and convex structure on the surface of the solder ball was measured by TEM. The composition ratio of tin and the height difference between the concave and convex are shown in Table 2.

### Preparation Example 15

Preparation of solder ball (XV) with concave-convex structure (T10-type solder ball; in 2N hydrochloric acid solution for 30 minutes)

2 g of T10-type solder balls were placed in a 2N hydrochloric acid solution (viscosity: 37.8 cps) containing 30% acid salt (modifier) of styrene-maleimide copolymer (SMA1000I), mixed and stirred for 30 minutes to perform an acidic etching step. Next, the solder balls were centrifuged to remove liquid. Next, the solder balls were washed with an ethanol solution containing 30 wt % rosin after aeration several times to obtain the modified solder balls (XV).

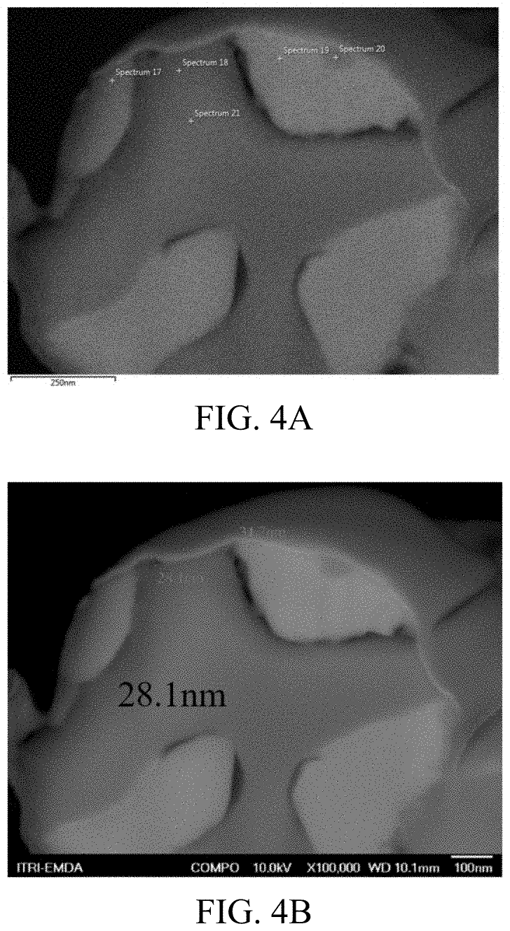

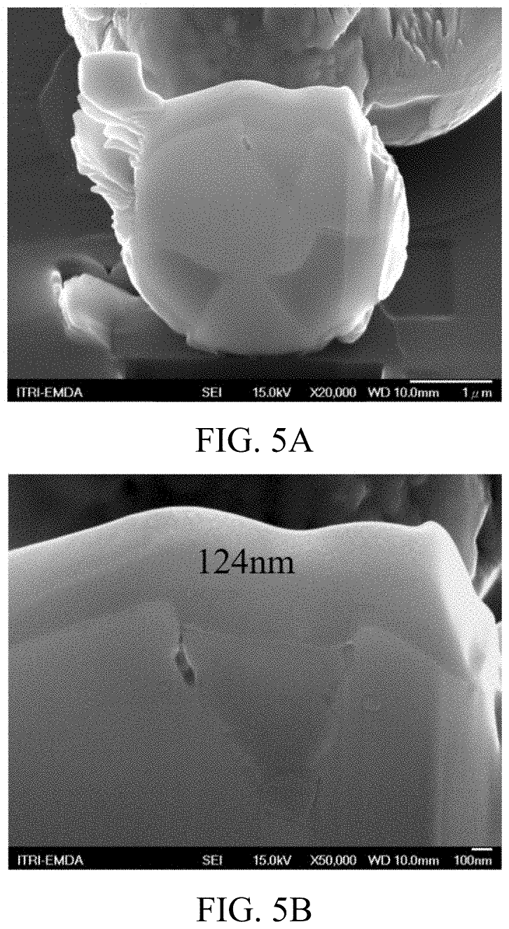

The elemental analysis of the modified solder ball was performed by SEM to obtain the composition ratio of tin in the tin-bismuth alloy, and sliced by FIB. The height of the concave structure and convex structure on the surface of the solder ball was measured by TEM. In this preparation example, a solder ball (XV) was taken and measured by TEM. The particle size thereof was 1 and the surface appearance thereof is shown in FIG. 4A. The measured height difference between the concave and convex was about 28.1 nm (as shown in FIG. 4B). A solder ball (XV) was taken and measured by TEM. The particle size thereof was 4 and the surface appearance thereof is shown in FIG. 5A. The measured height difference between the concave and convex was about 124 nm (as shown in FIG. 5B). The composition ratio of tin and the height difference between the concave and convex are shown in Table 2.

### Preparation Example 16

Preparation of solder ball (XVI) with concave-convex structure (T10-type solder ball; in 2N hydrochloric acid solution for 2 hours)

2 g of T10-type solder balls were placed in a 2N hydrochloric acid solution (viscosity: 37.8 cps) containing 30% acid salt (modifier) of styrene-maleimide copolymer (SMA1000I), mixed and stirred for 2 hours to perform an acidic etching step. Next, the solder balls were centrifuged to remove liquid. Next, the solder balls were washed with an ethanol solution containing 30 wt % rosin after aeration several times to obtain the modified solder balls (XVI).

The elemental analysis of the modified solder ball was performed by SEM to obtain the composition ratio of tin in the tin-bismuth alloy, and sliced by FIB. The height of the concave structure and convex structure on the surface of the solder ball was measured by TEM. The composition ratio of tin and the height difference between the concave and convex are shown in Table 2.

### Comparative Example 1

Unmodified T7-type solder balls were added to a flux to form a solder paste. The flux was formulated with the ratio of rosin/oleic acid/1,2-cyclohexanedicarboxylate diglycidyl ester/glutaric acid (4/1/1/4). The solid content of the solder paste was 80%. After that, the solder paste was printed on the electrodes by steel-plate printing, and it was observed whether the solder balls could be melted and connected to the electrodes after reflow at a reflow temperature of 160° C. The results are shown in Table 1.

### Example 1

The modified solder balls (I) were added to a flux to form a solder paste. The flux was formulated with the ratio of rosin/oleic acid/1,2-cyclohexanedicarboxylate diglycidyl ester/glutaric acid (4/1/1/4). The solid content of the solder paste was 80%. After that, the solder paste was printed on the electrodes by steel-plate printing, and the reflow effect was observed (it was observed that whether the solder balls could be melted and connected to the electrodes after reflow at a reflow temperature of 160° C.). The results are shown in Table 1.

### Example 2

The modified solder balls (II) were added to a flux to form a solder paste. The flux was formulated with the ratio of rosin/oleic acid/1,2-cyclohexanedicarboxylate diglycidyl ester/glutaric acid (4/1/1/4). The solid content of the solder paste was 80%. After that, the solder paste was printed on the electrodes by steel-plate printing, and the reflow effect was observed (it was observed that whether the solder balls could be melted and connected to the electrodes after reflow at a reflow temperature of 160° C.). The results are shown in Table 1.

### Example 3

The modified solder balls (III) were added to a flux to form a solder paste. The flux was formulated with the ratio of rosin/oleic acid/1,2-cyclohexanedicarboxylate diglycidyl ester/glutaric acid (4/1/1/4). The solid content of the solder paste was 80%. After that, the solder paste was printed on the electrodes by steel-plate printing, and the reflow effect was observed (it was observed that whether the solder balls could be melted and connected to the electrodes after reflow at a reflow temperature of 160° C.). The results are shown in Table 1.

### Example 4

The modified solder balls (IV) were added to a flux to form a solder paste. The flux was formulated with the ratio of rosin/oleic acid/1,2-cyclohexanedicarboxylate diglycidyl ester/glutaric acid (4/1/1/4). The solid content of the solder paste was 80%. After that, the solder paste was printed on the electrodes by steel-plate printing, and the reflow effect was observed (it was observed that whether the solder balls could be melted and connected to the electrodes after reflow at a reflow temperature of 160° C.). The results are shown in Table 1.

### Comparative Example 2

The modified solder balls (V) were added to a flux to form a solder paste. The flux was formulated with the ratio of rosin/oleic acid/1,2-cyclohexanedicarboxylate diglycidyl ester/glutaric acid (4/1/1/4). The solid content of the solder paste was 80%. After that, the solder paste was printed on the electrodes by steel-plate printing, and the reflow effect was observed (it was observed that whether the solder balls could be melted and connected to the electrodes after reflow at a reflow temperature of 160° C.). The results are shown in Table 1.

### Example 5

The modified solder balls (VI) were added to a flux to form a solder paste. The flux was formulated with the ratio of rosin/oleic acid/1,2-cyclohexanedicarboxylate diglycidyl ester/glutaric acid (4/1/1/4). The solid content of the solder paste was 80%. After that, the solder paste was printed on the electrodes by steel-plate printing, and the reflow effect was observed (it was observed that whether the solder balls could be melted and connected to the electrodes after reflow at a reflow temperature of 160° C.). The results are shown in Table 1.

### Example 6

The modified solder balls (VII) were added to a flux to form a solder paste. The flux was formulated with the ratio of rosin/oleic acid/1,2-cyclohexanedicarboxylate diglycidyl ester/glutaric acid (4/1/1/4). The solid content of the solder paste was 80%. After that, the solder paste was printed on the electrodes by steel-plate printing, and the reflow effect was observed (it was observed that whether the solder balls could be melted and connected to the electrodes after reflow at a reflow temperature of 160° C.). The results are shown in Table 1.

### Comparative Example 3

The modified solder balls (VIII) were added to a flux to form a solder paste. The flux was formulated with the ratio of rosin/oleic acid/1,2-cyclohexanedicarboxylate diglycidyl ester/glutaric acid (4/1/1/4). The solid content of the solder paste was 80%. After that, the solder paste was printed on the electrodes by steel-plate printing, and the reflow effect was observed (it was observed that whether the solder balls could be melted and connected to the electrodes after reflow at a reflow temperature of 160° C.). The results are shown in Table 1.

### Comparative Example 4

Unmodified T10-type solder balls were added to a flux to form a solder paste. The flux was formulated with the ratio of rosin/oleic acid/1,2-cyclohexanedicarboxylate diglycidyl ester/glutaric acid (4/1/1/4). The solid content of the solder paste was 60%. After that, the solder paste was printed on the electrodes by steel-plate printing, and it was observed whether the solder balls could be melted and connected to the electrodes after reflow at a reflow temperature of 160° C. The results are shown in Table 2.

### Example 7

The modified solder balls (IX) were added to a flux to form a solder paste. The flux was formulated with the ratio of rosin/oleic acid/1,2-cyclohexanedicarboxylate diglycidyl ester/glutaric acid (4/1/1/4). The solid content of the solder paste was 60%. After that, the solder paste was printed on the electrodes by steel-plate printing, and the reflow effect was observed (it was observed that whether the solder balls could be melted and connected to the electrodes after reflow at a reflow temperature of 160° C.). The results are shown in Table 2.

### Example 8

The modified solder balls (X) were added to a flux to form a solder paste. The flux was formulated with the ratio of rosin/oleic acid/1,2-cyclohexanedicarboxylate diglycidyl ester/glutaric acid (4/1/1/4). The solid content of the solder paste was 60%. After that, the solder paste was printed on the electrodes by steel-plate printing, and the reflow effect was observed (it was observed that whether the solder balls could be melted and connected to the electrodes after reflow at a reflow temperature of 160° C.). The results are shown in Table 2.

### Example 9

The modified solder balls (XI) were added to a flux to form a solder paste. The flux was formulated with the ratio of rosin/oleic acid/1,2-cyclohexanedicarboxylate diglycidyl ester/glutaric acid (4/1/1/4). The solid content of the solder paste was 60%. After that, the solder paste was printed on the electrodes by steel-plate printing, and the reflow effect was observed (it was observed that whether the solder balls could be melted and connected to the electrodes after reflow at a reflow temperature of 160° C.). The results are shown in Table 2.

### Example 10

The modified solder balls (XII) were added to a flux to form a solder paste. The flux was formulated with the ratio of rosin/oleic acid/1,2-cyclohexanedicarboxylate diglycidyl ester/glutaric acid (4/1/1/4). The solid content of the solder paste was 60%. After that, the solder paste was printed on the electrodes by steel-plate printing, and the reflow effect was observed (it was observed that whether the solder balls could be melted and connected to the electrodes after reflow at a reflow temperature of 160° C.). The results are shown in Table 2.

### Comparative Example 5

The modified solder balls (XIII) were added to a flux to form a solder paste. The flux was formulated with the ratio of rosin/oleic acid/1,2-cyclohexanedicarboxylate diglycidyl ester/glutaric acid (4/1/1/4). The solid content of the solder paste was 60%. After that, the solder paste was printed on the electrodes by steel-plate printing, and the reflow effect was observed (it was observed that whether the solder balls could be melted and connected to the electrodes after reflow at a reflow temperature of 160° C.). The results are shown in Table 2.

### Example 11

The modified solder balls (XIV) were added to a flux to form a solder paste. The flux was formulated with the ratio of rosin/oleic acid/1,2-cyclohexanedicarboxylate diglycidyl ester/glutaric acid (4/1/1/4). The solid content of the solder paste was 60%. After that, the solder paste was printed on the electrodes by steel-plate printing, and the reflow effect was observed (it was observed that whether the solder balls could be melted and connected to the electrodes after reflow at a reflow temperature of 160° C.). The results are shown in Table 2.

### Example 12

The modified solder balls (XV) were added to a flux to form a solder paste. The flux was formulated with the ratio of rosin/oleic acid/1,2-cyclohexanedicarboxylate diglycidyl ester/glutaric acid (4/1/1/4). The solid content of the solder paste was 60%. After that, the solder paste was printed on the electrodes by steel-plate printing, and the reflow effect was observed (it was observed that whether the solder balls could be melted and connected to the electrodes after reflow at a reflow temperature of 160° C.). The results are shown in Table 2.

### Comparative Example 6

The modified solder balls (XVI) were added to a flux to form a solder paste. The flux was formulated with the ratio of rosin/oleic acid/1,2-cyclohexanedicarboxylate diglycidyl ester/glutaric acid (4/1/1/4). The solid content of the solder paste was 60%. After that, the solder paste was printed on the electrodes by steel-plate printing, and the reflow effect was observed (it was observed that whether the solder balls could be melted and connected to the electrodes after reflow at a reflow temperature of 160° C.). The results are shown in Table 2.

TABLE 1

| | | | | | Height | | |
|---|---|---|---|---|---|---|---|
| | | | | | difference | | |
| | | | | | between | | |
| | | Acidic | | | concave | Proportion | |
| Examples/ | | etching | | | and | of tin in | |
| Com. | Solder | conditions | | | convex | tinbismuth | |
| Examples | ball | (con./period) | Modifier | Modified solder ball | (nm) | alloy | Reflow effect |
| Com. | T7 | no treatment | — | — | — | 56.5 | X |
| Example | | | | | | 52.32 | |
| 1 | | | | | | 53.6 | |
| Example | T7 | 1N/5 minutes | 30% | (1) | 10-200 | 51.2 | O |
| 1 | | | SMA | | | 51.6 | |
| | | | | | | 50.9 | |
| Example | T7 | 1N/30 | 30% | (11) | 10-200 | 40.1 | O |
| 2 | | minutes | SMA | | | 41.81 | |
| | | | | | | 39.61 | |
| Example | T7 | 1N/30 | 40% | (III) | 10-200 | 40.2 | O |
| 3 | | minutes | SMA | | | 41.3 | |
| | | | | | | 40.5 | |
| Example | T7 | 1N/30 | glycerol | (IV) | 10-200 | 40.55 | O |
| 4 | | minutes | | | | 41.61 | |
| | | | | | | 39.89 | |
| Com. | T7 | 1N/2 hours | 30% | (V) | >200 | 24 | X |
| Example | | | SMA | | | 26.28 | |
| 2 | | | | | | 27.01 | |
| Example | T7 | 2N/5 minutes | 30% | (VI) | 10-200 | 50.51 | O |
| 5 | | | SMA | | | 47.8 | |
| | | | | | | 51.13 | |
| Example | T7 | 2N/30 | 30% | (VII) | 10-200 | 39.76 | O |
| 6 | | minutes | SMA | | | 37.2 | |
| | | | | | | 36.48 | |
| Com. | T7 | 2N/2 hours | 30% | (VIII) | >200 | 24 | X |
| Example | | | SMA | | | 26.3 | |
| 3 | | | | | | 25.6 | |

TABLE 2

| | | | | | Height | | |
|---|---|---|---|---|---|---|---|
| | | | | | difference | | |
| | | | | | between | | |
| | | Acidic | | | concave | Proportion | |
| Examples/ | | etching | | | and | of tin in | |
| Com. | Solder | conditions | | Modified | convex | tinbismuth | Reflow |
| Examples | ball | (con./period) | Modifier | solder ball | (nm) | alloy | effect |
| Com. | T10 | no treatment | — | — | — | 45.01 | X |
| Example | | | | | | 46.15 | |
| 4 | | | | | | 46.08 | |
| Example | T10 | 1N/5 minutes | 30% | (IX) | 10-200 | 38.70 | O |
| 7 | | | SMA | | | 39.20 | |
| | | | | | | 41.10 | |
| Example | T10 | 1N/30 | 30% | (X) | 10-200 | 30.50 | O |
| 8 | | minutes | SMA | | | 32.10 | |
| | | | | | | 29.80 | |
| Example | T10 | 1N/30 | 40% | (XI) | 10-200 | 30.72 | O |
| 9 | | minutes | SMA | | | 32.09 | |
| | | | | | | 31.52 | |
| Example | T10 | 1N/30 | glycerol | (XII) | 10-200 | 30.79 | O |
| 10 | | minutes | | | | 31.88 | |
| | | | | | | 31.25 | |
| Com. | T10 | 1N/2 hours | 30% | (XIII) | >200 | 27.15 | X |
| Example | | | SMA | | | 22.10 | |
| 5 | | | | | | 23.00 | |
| Example | T10 | 2N/5 minutes | 30% | (XIV) | 10-200 | 37.40 | O |
| 11 | | | SMA | | | 38.40 | |
| | | | | | | 40.10 | |
| Example | T10 | 2N/30 | 30% | (XV) | 10-200 | 27.90 | O |
| 12 | | minutes | SMA | | | 28.5 | |
| | | | | | | 31.60 | |
| Com. | T10 | 2N/2 hours | 30% | (XVI) | >200 | 20.60 | X |
| Example | | | SMA | | | 23.30 | |
| 6 | | | | | | 23.60 | |

According to Table 1 and Table 2, it can be seen from the test results that when the acidic etching period of the disclosed solder balls is 5 minutes (such as Examples 1, 3, 5 and 7) and 30 minutes (such as Examples 2, 4, 6 and 8), the acidic etching depth can be controlled, so that the height difference between the concave and convex is between 10 nm and 200 nm, and the composition ratio of tin in the tin-bismuth alloy is between 28% and 52%. In this way, after the solder balls are prepared into the solder paste, the solder paste can be effectively connected to the electrodes during the reflow. On the contrary, the solder paste made of unmodified solder balls (such as Comparative Examples 1 and 4) cannot be effectively reflowed at a temperature of 160° C., and then cannot be effectively attached to the electrodes. When the size of the solder balls is selected T7 type (for example, the particle size is between 2 μm and 11 μm) and T10 type (for example, the particle size is between 1 μm and 4 μm), using strong acid and the acidic etching period exceeding two hours may cause the solder balls to be over-etched or even to crack. The solder paste cannot be effectively reflowed at 160° C. and attached on the electrodes.

The self-assembled solder paste is patterned by a steel-plate printing process. After reflow, it is assembled to the electrode, and then the micro light-emitting diode is joined thereon. As the size of the existing micro light-emitting diodes is reduced to the wafer size of 30*15 μm², the size of the electrodes is also reduced to 15*10 μm², and the spacing between the electrodes is reduced to 10 μm. The solder balls with a size between 0.5 μm and 12 μm are selected. Through surface modification, the concentration of the oxide layer on the surface of the solder ball is reduced, resulting in concave and convex structures. The solder balls can thus be self-aggregated on the electrodes after reflow, which can speed up the process speed, solve the reflowability, and improve the connection with the electrodes, so that the micro-LED display can be mass-produced. In addition, the disclosed self-assembled solder paste with low-temperature (160° C.) reflow characteristics can also solve the problem that the imprint head of the mass transfer head fails due to high temperature reflow (260° C.).

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A solder ball with a concave-convex structure, comprising:
tin-bismuth alloy comprising a plurality of concave portions and convex portions on a surface thereof, wherein the concave portions and the convex portions have a height difference which is between 10 nm and 200 nm, and tin in the tin-bismuth alloy has a proportion which is between 28% and 52%.

2. The solder ball with a concave-convex structure as claimed in claim 1, wherein the solder ball has a particle size ranging from 0.5 μm to 12 μm.

3. A method for preparing a solder ball with a concave-convex structure, comprising:
providing an acidic etching solution, wherein the acidic etching solution comprises an acid and a modifier;
placing a solder ball in the acidic etching solution to perform an acidic etching step; and
cleaning the solder ball subjected to the acidic etching step several times with a solution containing an antioxidant protective agent to prepare the solder ball with a concave-convex structure as claimed in claim 1.

4. The method for preparing a solder ball with a concave-convex structure as claimed in claim 3, wherein the acid comprises an inorganic acid or an organic acid.

5. The method for preparing a solder ball with a concave-convex structure as claimed in claim 4, wherein the acid comprises hydrochloric acid, nitric acid, oxalic acid, carboxylic acid, glutaric acid, hexanedioic acid or oleic acid.

6. The method for preparing a solder ball with a concave-convex structure as claimed in claim 3, wherein the acidic etching solution has a viscosity ranging from 30 cps to 3000 cps.

7. The method for preparing a solder ball with a concave-convex structure as claimed in claim 3, wherein the modifier comprises polyol or ionic polymer.

8. The method for preparing a solder ball with a concave-convex structure as claimed in claim 7, wherein the polyol comprises ethylene glycol, glycerol or propylene glycol.

9. The method for preparing a solder ball with a concave-convex structure as claimed in claim 7, wherein the ionic polymer comprises anionic polyacrylamide, acid salt of styrene-maleimide copolymer or ammonium salt of styrene-maleic anhydride copolymer.

10. The method for preparing a solder ball with a concave-convex structure as claimed in claim 3, wherein the acidic etching step has a period which is between 5 minutes and 4 hours.

11. The method for preparing a solder ball with a concave-convex structure as claimed in claim 3, wherein the antioxidant protective agent comprises rosin, rosin derivatives, fatty acid, titanium complex, zirconium complex or long-carbon-chain thiol.

12. A solder paste, comprising:
a colloidal composition comprising rosin, oleic acid, epoxy resin and organic polyacid; and
the solder ball with a concave-convex structure as claimed in claim 1 mixed in the colloidal composition.

13. The solder paste as claimed in claim 12, wherein the epoxy resin comprises 1,2-cyclohexanedicarboxylate diglycidyl ester.

14. The solder paste as claimed in claim 12, wherein the organic polyacid comprises glutaric acid.

15. The solder paste as claimed in claim 13, wherein rosin, oleic acid, 1,2-cyclohexanedicarboxylate diglycidyl ester and organic polyacid have a ratio of 30-50:5-20:5-20: 30-50.
